(19) United States
(12) Patent Application Publication
(10) Pub. No.: US 2024/0322040 A1
(43) Pub. Date: Sep. 26, 2024

(54) THRESHOLD VOLTAGE TUNING OF NFET VIA IMPLEMENTATION OF AN ALUMINUM-FREE CONDUCTIVE LAYER

(71) Applicant: Taiwan Semiconductor Manufacturing Company, Ltd., Hsin-Chu (TW)

(72) Inventors: Pei Ying Lai, Hsinchu (TW); Yi Hsuan Chen, Hsinchu City (TW); Yen-Fu Chen, Taipei (TW); Jia-Yun Xu, Hsinchu City (TW); Cheng-Hao Hou, Hsinchu City (TW); Da-Yuan Lee, Hsinchu County (TW); Chi On Chui, Hsinchu City (TW)

(21) Appl. No.: 18/478,365

(22) Filed: Sep. 29, 2023

Related U.S. Application Data
(60) Provisional application No. 63/491,294, filed on Mar. 21, 2023.

(51) Int. Cl. H01L 29/78; H01L 21/8238; H01L 27/092; H01L 29/06; H01L 29/423; H01L 29/49; H01L 29/66

(52) U.S. Cl. CPC H01L 29/785; H01L 21/823807; H01L 21/823821; H01L 21/823842; H01L 27/0924; H01L 29/0665; H01L 29/42392; H01L 29/4966; H01L 29/66545; H01L 29/66795

(57) ABSTRACT

A first n-type transistor includes a first channel component, an undoped first gate dielectric layer disposed over the first channel component, and a first gate electrode disposed over the undoped first gate dielectric layer. A second n-type transistor includes a second channel component and a doped second gate dielectric layer disposed over the second channel component. The second gate dielectric layer is doped with a p-type dipole material. A second gate electrode is disposed over the second gate dielectric layer. At least one of the first n-type transistor or the second n-type transistor further includes an aluminum-free conductive layer. The aluminum-free conductive layer is disposed between the first gate dielectric layer and the first gate electrode or between the second gate dielectric layer and the second gate electrode.

### PRIORITY DATA

The present application is a utility patent application of provisional U.S. Patent Application No. 63/491,294, filed on Mar. 21, 2023, and entitled “NFET THRESHOLD VOLTAGE TUNING OF ALUMINUM-BASED P-DIPOLES”, the disclosure of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs. For example, as device sizes shrink, undesirable diffusion of elements between adjacent device components could occur more easily, and the unintended negative effects may be more pronounced. In some cases, an unintended aluminum diffusion between a gate dielectric layer and a metal gate electrode could interfere with the proper tuning of threshold voltages. As a result, the device performance may not be optimal.

Therefore, although conventional methods of fabricating semiconductor devices have generally been adequate, they have not been satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a perspective view of an IC device in the form of a FinFET according to various aspects of the present disclosure.

FIG. 1B is a planar top view of an IC device in the form of a FinFET according to various aspects of the present disclosure.

FIG. 1C is a perspective view of an IC device in the form of a GAA device according to various aspects of the present disclosure.

FIGS. 2-27 are cross-sectional side views illustrating various process flows of forming an IC device according to various aspects of the present disclosure.

FIG. 28 is a block diagram of a manufacturing system according to various aspects of the present disclosure.

FIG. 29 is a flowchart illustrating a method of fabricating a semiconductor device according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices, and more particularly to field-effect transistors (FETs), such as three-dimensional fin-shaped FETs (FinFETs) or gate-all-around (GAA) devices. In that regard, a FinFET device is a fin-like field-effect transistor device, and a GAA device is a multi-channel field-effect transistor device. FinFET devices and GAA devices have both been gaining popularity recently in the semiconductor industry, since they offer several advantages over traditional Metal-Oxide Semiconductor Field Effect Transistor (MOSFET) devices (e.g., “planar” transistor devices). These advantages may include better chip area efficiency, improved carrier mobility, and fabrication processing that is compatible with the fabrication processing of planar devices. Thus, it may be desirable to design an integrated circuit (IC) chip using FinFET devices or GAA devices for a portion of, or the entire IC chip.

However, in spite of the advantages offered by the FinFET devices and/or GAA devices, certain challenges may still remain in IC applications in which FinFET or GAA devices are implemented. For instance, conventional threshold voltage (Vt) tuning may be done at least in part by a dipole drive-in method, in which a gate dielectric layer becomes doped by the dipole drive-in. For certain IC applications, the dipole drive-in may allow the transistors to achieve a different threshold voltage than the transistors for which the dipole drive-in process was not performed. The transistor for which the dipole drive-in process was performed may be referred to as a dipole drive-in transistor, and the other transistor for which the dipole drive-in was not performed may be referred to as a counterpart transistor, and their differently-tuned threshold voltages are specifically configured as such to facilitate their intended functionalities in different circuit applications.

However, in some cases, the dipole drive-in dopant (e.g., aluminum) may be present in the metal gate electrode formed over the gate dielectric layer (which is supposed to be undoped) of the counterpart transistor. When the gate dielectric comes into direct contact with the metal electrode, the atoms of the dipole drive-in dopant (e.g., aluminum atoms) may diffuse from the metal gate electrode into the gate dielectric layer, thereby causing the gate dielectric layer of the counterpart transistor to become partially doped, which is not intended. For example, the dipole drive-in process may use aluminum oxide (AlOₓ), titanium aluminum nitride (TiₓAl_{y}N_{z}), or aluminum nitride (AlNₓ) as a dopant source. The aluminum from these materials may diffuse into the gate dielectric layer. This unintentional diffusion may lessen the threshold voltage difference between the dipole drive-in transistor and the counterpart transistor, which is undesirable, because it may adversely interfere with the intended functioning of the counterpart and/or dipole drive-in transistors in their circuit applications.

To address the issues discussed above, the present disclosure implements an aluminum-free conductive layer between the gate dielectric layers and the metal gate electrodes. Such a layer can block (or at least reduce) the undesirable diffusion of aluminum discussed above, which helps the dipole drive-in transistors and the counterpart transistors to maintain their intended threshold voltage differences. Since such a layer is also conductive, its implementation would not unduly increase parasitic resistance either. Consequently, device performance may be optimized. The various aspects of the present disclosure will now be discussed below in more detail.

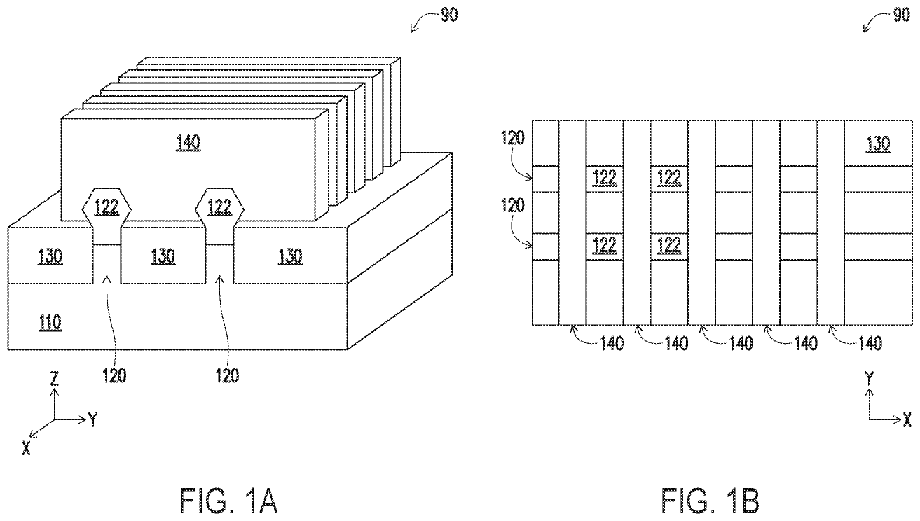

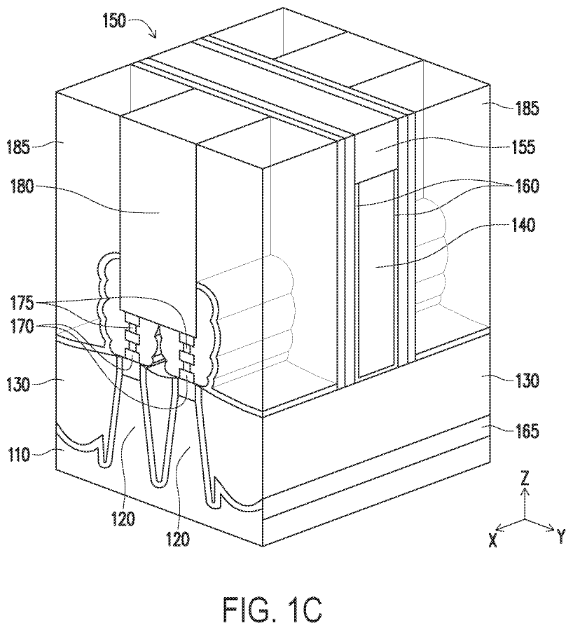

FIGS. 1A-1C will describe the basic structures of example FinFET and GAA devices. Referring now to FIGS. 1A and 1B, a three-dimensional perspective view and a top view of a portion of an Integrated Circuit (IC) device 90 are illustrated, respectively. The IC device 90 may be an intermediate device fabricated during processing of an IC, or a portion thereof, that may comprise static random-access memory (SRAM) and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells. The present disclosure is not limited to any particular number of devices or device regions, or to any particular device configurations, unless otherwise claimed. For example, although the IC device 90 as illustrated is a three-dimensional FinFET device, the concepts of the present disclosure may also apply to planar FET devices or GAA devices.

Referring to FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP. AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 are elongated fin-like structures that protrude upwardly out of the substrate 110. As such, the active regions 120 may be interchangeably referred to as fin structures 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain features 122 formed over the fin structures 120. The source/drain features 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIG. 1B, multiple fin structures 120 are oriented lengthwise along the X-direction, and multiple gate structures 140 are oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

It is also understood that the various aspects of the present disclosure discussed below may apply to multi-channel devices such as Gate-All-Around (GAA) devices. FIG. 1C illustrates a three-dimensional perspective view of an example GAA device 150. For reasons of consistency and clarity, similar components in FIG. 1C and FIGS. 1A-1B will be labeled the same. For example, active regions such as fin structures 120 rise vertically upwards out of the substrate 110 in the Z-direction. The isolation structures 130 provide electrical separation between the fin structures 120. The gate structure 140 is located over the fin structures 120 and over the isolation structures 130. A mask 155 is located over the gate structure 140, and gate spacers 160 are located on sidewalls of the gate structure 140. A capping layer 165 is formed over the fin structures 120 to protect the fin structures 120 from oxidation during the forming of the isolation structures 130.

A plurality of nano-structures 170 is disposed over each of the fin structures 120. The nano-structures 170 may include nano-sheets, nano-tubes, or nano-wires, or some other type of nano-structure that extends horizontally in the X-direction. Portions of the nano-structures 170 under the gate structure 140 may serve as the channels of the GAA device 150. Dielectric inner spacers 175 may be disposed between the nano-structures 170. In addition, although not illustrated for reasons of simplicity, each of the nano-structures 170 may be wrapped around circumferentially by a gate dielectric as well as a gate electrode. In the illustrated embodiment, the portions of the nano-structures 170 outside the gate structure 140 may serve as the source/drain features of the GAA device 150. However, in some embodiments, continuous source/drain features may be epitaxially grown over portions of the fin structures 120 outside of the gate structure 140. Regardless, conductive source/drain contacts 180 may be formed over the source/drain features to provide electrical connectivity thereto. An interlayer dielectric (ILD) 185 is formed over the isolation structures 130 and around the gate structure 140 and the source/drain contacts 180.

Regardless of whether the transistors of an IC are implemented as a FinFET of FIGS. 1A-1B or a GAA device of FIG. 1C, it is understood that they may benefit from the concepts of the present disclosure, as discussed below in more detail.

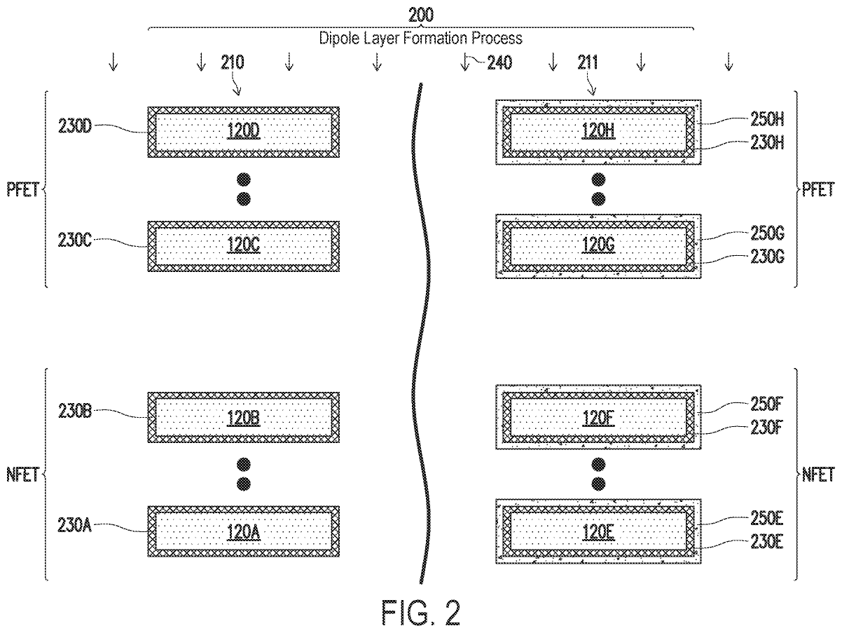

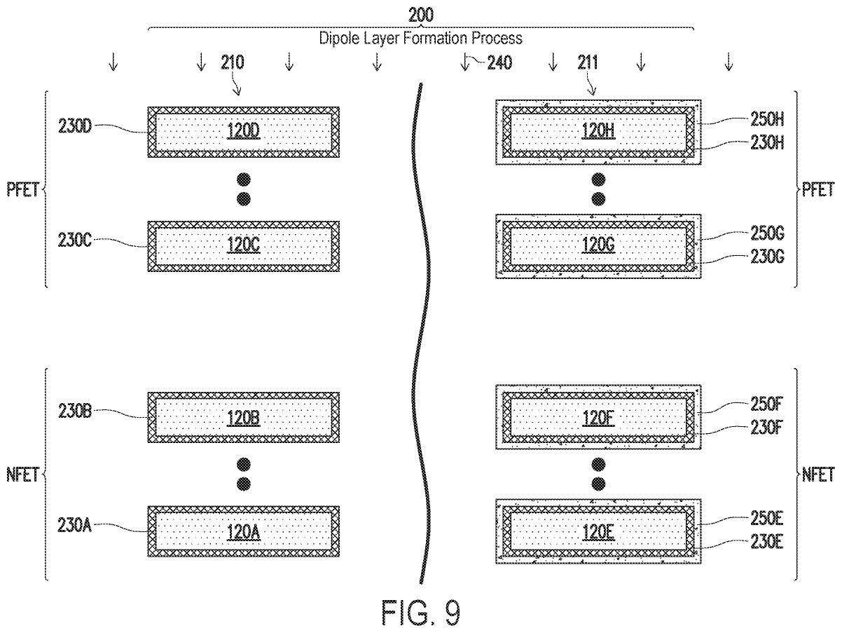

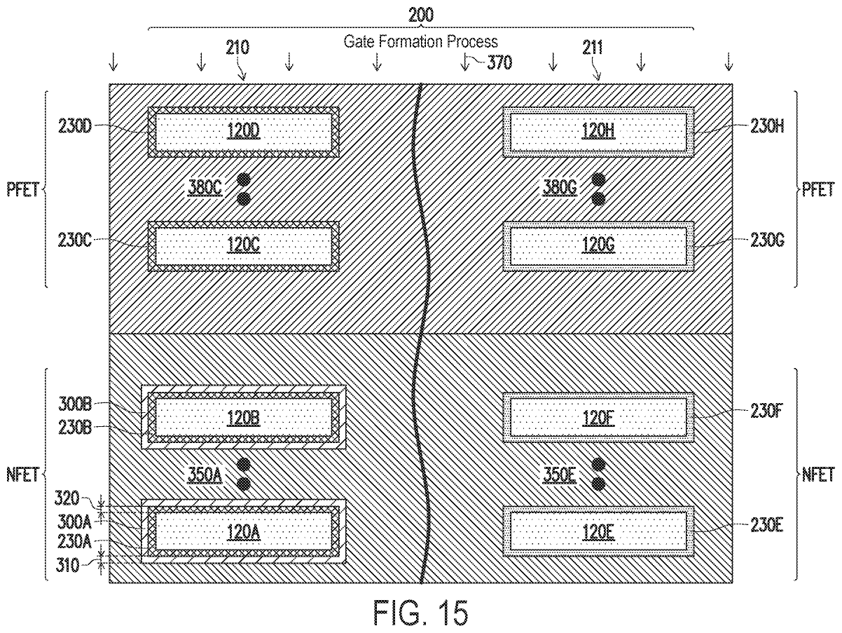

FIGS. 2-22 are a series of diagrammatic fragmentary cross-sectional side views illustrating process flows to fabricate an example IC device 200 according to different embodiments of the present disclosure. Specifically, FIGS. 2-8 illustrate the process flow corresponding to a first embodiment of the present disclosure, FIGS. 9-15 illustrate the process flow corresponding to a second embodiment of the present disclosure, and FIGS. 15-22 illustrate the process flow corresponding to a third embodiment of the present disclosure.

Referring now to FIG. 2, the IC device 200 includes a plurality of vertical stacks of transistors, such as a vertical stack 210 and a vertical stack 211. Each of the vertical stacks 210-211 of transistors may be associated with a different threshold voltage (Vt) and/or may be configured or used for a different circuit application. In the illustrated embodiment, the vertical stack 210 is a part of a complementary field effect transistor (CFET) that does not (or will not) have a dipole drive-in, and the vertical stack 211 is a part of a CFET that does (or will) have a dipole drive-in. As such, the transistors in the vertical stack 210 may also be referred to as CFET counterpart devices, and the transistors in the vertical stack 211 may also be referred to as CFET drive-in devices.

The vertical stacks 210 and 211 each include one or more n-type transistors (e.g., NFETs) and one or more p-type transistors (e.g., PFETs). For example, the vertical stack 210 includes an NFET and a PFET that is disposed vertically over the NFET. The NFET may include a plurality of channel components 120A-120B, and the PFET may include a plurality of channel components 120C-120D. The channel components 120A-120D are portions of active regions. The channel components 120A-120D may be patterned into nano-structure channels, for example, as nano-sheets, nano-tubes, nano-wires, nano-bars, etc. The channel components 120A-120D may each include a semiconductive material, for example, a silicon (Si) material, a silicon germanium (SiGe) material, or a III-V group compound (e.g., a compound that includes an element from the III-group of the periodic table as well as an element from the V-group of the periodic table).

Similar to the vertical stack 210, the vertical stack 211 also includes an NFET and a PFET disposed over the NFET. The NFET of the vertical stack 211 may include a plurality of channel components 120E-120F, and the PFET of the vertical stack 211 may include a plurality of channel components 120G-120H, where each of the channel components 120E-120H may be patterned as nano-structure channels that contain a semiconductive material, such as nano-sheets, nano-tubes, nano-wires, nano-bars, etc.

It is understood that each of the NFETs and the PFETs of the vertical stacks 210 and 211 may optionally include more than two channel components. For example, the NFET of the vertical stack 210 may optionally include additional channel components between the channel component 120A and 120B, and the PFET of the vertical stack 210 may optionally include additional channel components between the channel component 120C and 120D, and the same is true for the NFET and the PFET of the vertical stack 211. These optional additional channel components are conceptually represented as a plurality of vertical dots in FIG. 2 for reasons of simplicity. It is also understood that while FIG. 2 shows that the PFET is disposed over the NFET in both of the vertical stacks 210-211 in this embodiment, the reverse may be true in other embodiments. For example, the NFET may be disposed over the PFET in either, or both, of the vertical stacks 210-211 in alternative embodiments.

The channel components 120A-120H are circumferentially wrapped around (e.g., in 360 degrees) by gate dielectric layers 230A-230H, respectively. The gate dielectric layers 230A-230H include high-k dielectric materials, which are dielectric materials whose dielectric constant is greater than a dielectric constant of silicon dioxide. In some embodiments, the gate dielectric layers 230A-230H include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, or combinations thereof.

Still referring to FIG. 2, a dipole layer formation process 240 is performed to the IC device 200. The dipole layer formation process 240 may utilize one or more deposition processes, such as chemical vapor deposition (CVD), physical vapor deposition (PVD), atomic layer deposition (ALD), or combinations thereof, to deposit p-dipole dopant source layers over the gate dielectric layers 230E-230H of the vertical stack 211. For example, p-dipole dopant source layers 250E, 250F, 250G, and 250H are deposited over the gate dielectric layers 230E-230H, respectively. In the cross-sectional side view of FIG. 2, the p-dipole dopant source layers 250E-250H circumferentially surround (e.g., in 360 degrees) the top, bottom, left, and right surfaces of their respective gate dielectric layers 230E-230H, respectively. In some embodiments, the p-dipole dopant source layers 250E-250H include aluminum-based p-dipoles. For example, the p-dipole dopant source layers 250E-250H may include aluminum oxide (AlOₓ), titanium aluminum nitride (TiₓAl_{y}N_{z}), aluminum nitride (AlNₓ), or combinations thereof (where x, y, and z are positive integers). Note that no p-dipole dopant source layers are formed over the gate dielectric layers 230A-230D of the vertical stack 210, since the transistors of the vertical stack 210 are meant to be counterpart devices (as opposed to the dipole drive-in devices).

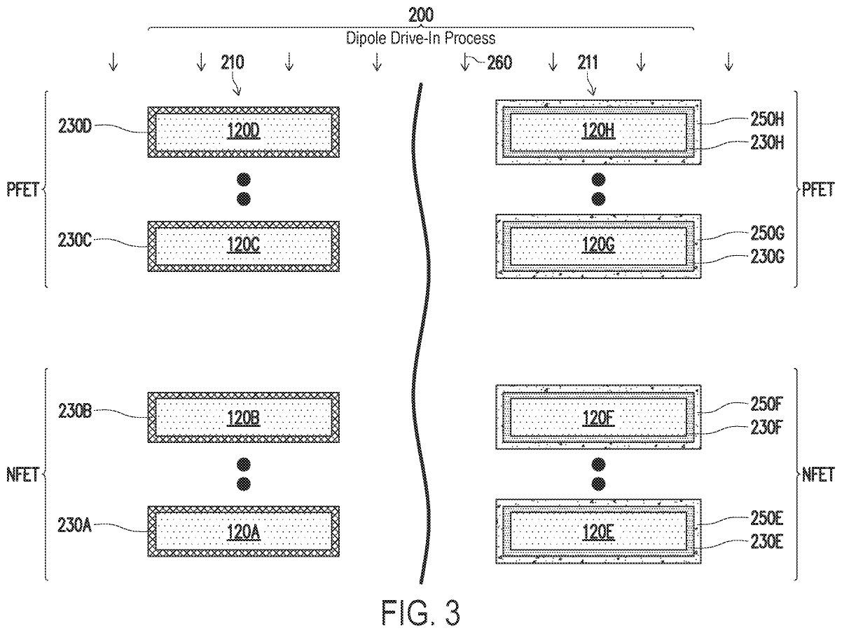

Referring now to FIG. 3, a dipole drive-in process 260 is performed to drive the atoms of the p-dipole dopant source layers 250E-250H into the gate dielectric layers 230E-230H. In some embodiments, the dipole drive-in process 260 includes one or more thermal annealing processes. The thermal annealing processes help facilitate a movement of the atoms (e.g., aluminum atoms or other suitable atoms) from the p-dipole dopant source layers 250E-250H into their respective gate dielectric layers 230E-230H wrapped thereunder. As a result, the gate dielectric layers 230E-230H of the vertical stack 211 become doped gate dielectric layers 230E-230H after the dipole drive-in process 260 has been performed. In some embodiments, the gate dielectric layers 230E-230H of the vertical stack 211 become doped with aluminum. In other embodiments, the gate dielectric layers 230E-230H of the vertical stack 211 are doped with a dipole material other than aluminum. In comparison, the gate dielectric layers 230A-230D of the vertical stack 210 still remain undoped.

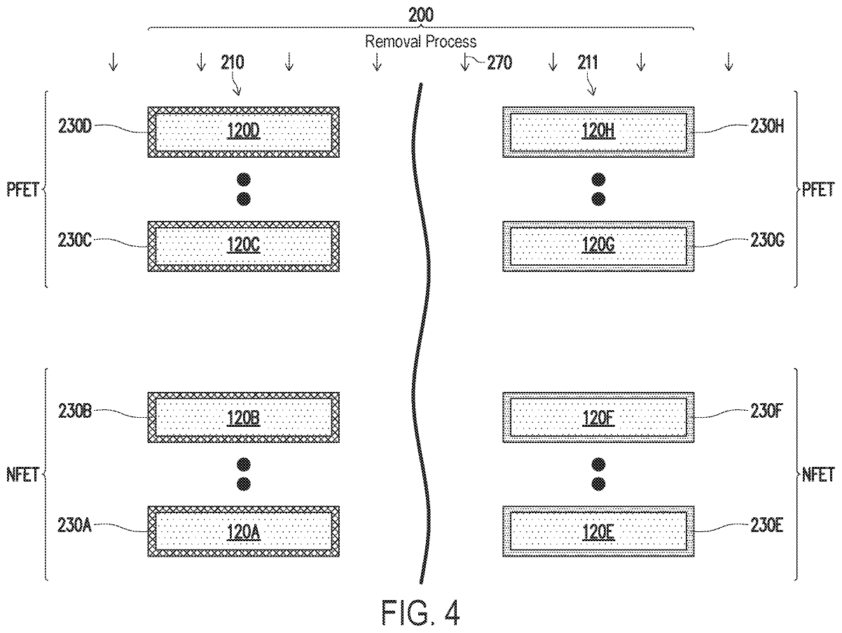

Referring now to FIG. 4, a removal process 270 is performed to the IC device 200 to remove the remaining portions of the p-dipole dopant source layers 250E-250H. In some embodiments, the removal process 270 may include one or more etching processes that etch away the p-dipole dopant source layers 250E-250H without substantially affecting the rest of the components of the IC device 200. For example, the one or more etching processes may be configured with a sufficient amount of etching selectivity between the p-dipole dopant source layers 250E-250H and the gate dielectric layers 230A-230H. As such, the p-dipole dopant source layers 250E-250H may be etched away at a substantially greater rate (e.g., five times more or ten times more) than the gate dielectric layers 230A-230H. As a result, the p-dipole dopant source layers 250E-250H may be completely removed, while the gate dielectric layers 230A-230H still remain.

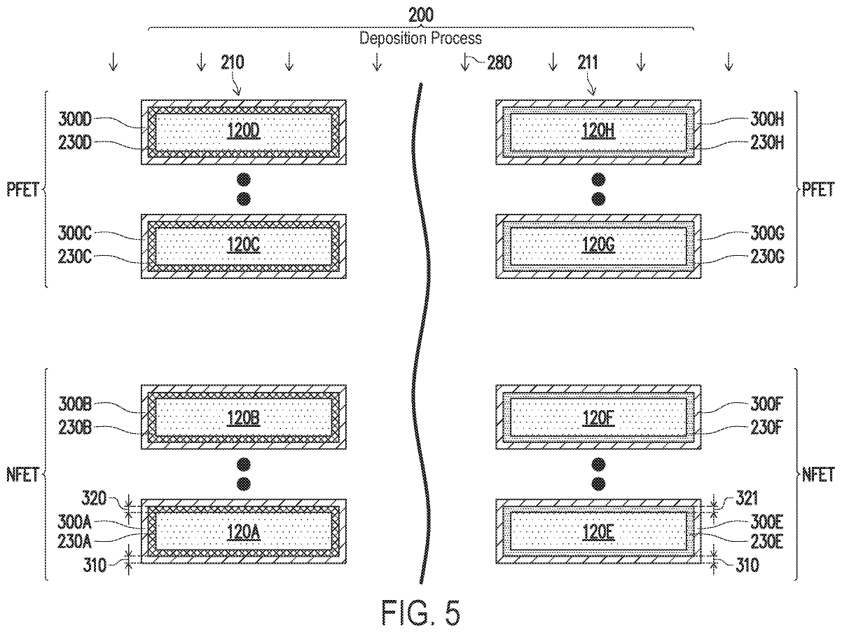

Referring now to FIG. 5, a deposition process 280 is performed to the IC device 200 to form an aluminum-free conductive layer over each of the gate dielectric layers 230A-230D of the vertical stack 210 and over each of the gate dielectric layers 230E-230H of the vertical stack 211. For example, aluminum-free conductive layers 300A. 300B, 300C, 300D are formed to circumferentially surround (e.g., in 360 degrees) the gate dielectric layers 230A-230D, respectively, and aluminum-free conductive layers 300E. 300F. 300G, 300H are formed to circumferentially surround (e.g., in 360 degrees) the gate dielectric layers 230E-230H, respectively, in the cross-sectional side view of FIG. 5. The aluminum-free conductive layers 300A-300H each include a conductive material that does not contain aluminum. In some embodiments, the aluminum-free conductive layers 300A-300H do not contain any type of p-type material. In some embodiments, the aluminum-free conductive layers 300A-300D are titanium nitride (TiN) layers. Note that although the conductive layers 300A-300H are formed to be free of aluminum in the embodiment discussed above, they may be free of other types of P-type dipole materials as well in other embodiments.

In some embodiments, the deposition process 280 may include ALD, CVD, PVD, or combinations thereof. The parameters of the deposition process 280 may be carefully configured to accurately control a thickness 310 of each of the aluminum-free conductive layers 300A-300H. In some embodiments, the thickness 310 is in a range between about 0.3 and about 2.5 nanometers. The thickness 310 is also correlated with the thicknesses of one or more other components of the IC device 200. For example, the gate dielectric layers 300A-300H may each have a thickness 320, and the gate dielectric layers 230E-230H may each have a thickness 321, which are directly correlated with the thickness 310 of the aluminum-free conductive layers 300A-300D. In some embodiments, a ratio between the thickness 310 and the thickness 320 is in a range between about 0.1:1 and about 5:1, and a ratio between the thickness 310 and the thickness 321 is in a range between about 0.1:1 and about 5:1.

The above ranges are not randomly chosen but rather specifically configured to optimize the performance of the IC device 200. For example, as will be discussed in more detail below, the aluminum-free conductive layers 300A-300H are implemented to prevent or reduce undesirable diffusion (e.g., diffusion of aluminum) between the gate dielectric layers 230A-230H and the metal gate electrodes that will be formed in a subsequent process. If the aluminum-free conductive layers 300A-300H are too thin, they may not adequately serve their intended purposes of blocking the undesirable aluminum diffusion. On the other hand, if the aluminum-free conductive layers 300A-300H are too thick, they may consume an excessive amount of chip space, which is valuable as device sizes continue to shrink. Furthermore, if the aluminum-free conductive layers 300A-300H are too thick, they could also adversely interfere with the threshold voltage tuning of their respective transistors. Here, the above ranges ensure that the aluminum-free conductive layers 300A-300H are thick enough to adequately block the undesirable diffusion, while thin enough to conserve chip space and not interfere with the tuning of threshold voltages.

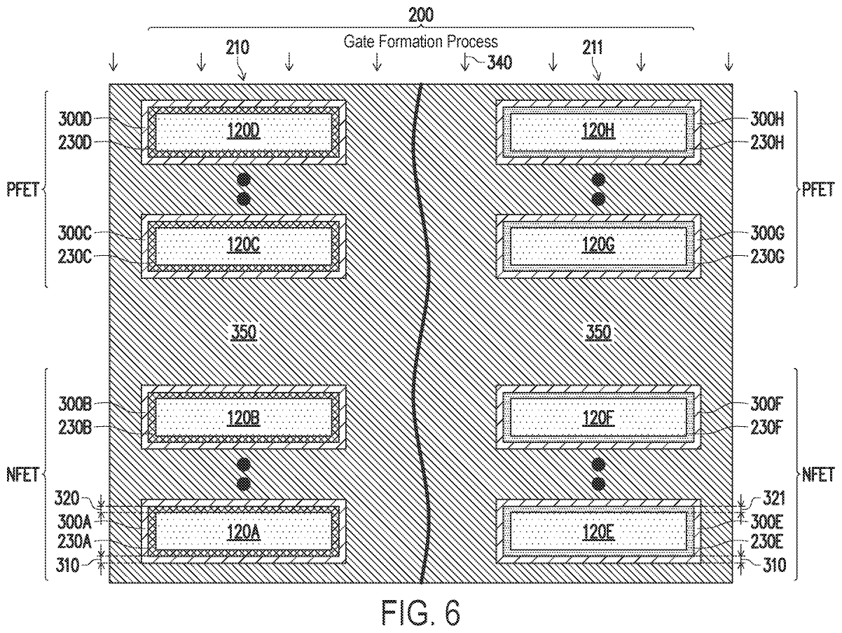

Referring now to FIG. 6, a gate formation process 340 is performed to the IC device 200 to form a metal gate electrode layer 350 over each of the aluminum-free conductive layers 300A-300H. For example, the metal gate electrode layer 350 is formed by one or more deposition processes, such as ALD, CVD, or PVD, and it circumferentially surrounds (e.g., in 360 degrees) each of the aluminum-free conductive layers 300A-300H in the cross-sectional side view of FIG. 6. Note that the metal gate electrode layer 350 formed over the vertical stack 210 may be electrically and/or physically separate from the metal gate electrode layer 350 formed over the vertical stack 211 in some embodiments.

The metal gate electrode layer 350 contains an n-type work function metal layer to tune a threshold voltage of the NFET of the vertical stack 210 and the NFET of the vertical stack 211. In some embodiments, the n-type work function metal layer includes an aluminum-containing metal, such as titanium aluminum carbide (TiₓAl_{y}C_{z}). A fill metal layer is formed over the work function metal layer and may serve as a main conductive portion of the gate electrode. In some embodiments, the fill metal layer may include titanium (Ti), tungsten (W), tantalum (Ta), copper (Cu), cobalt (Co), etc.

As discussed above, the gate dielectric layers 230E-230H of the vertical stack 211 are doped with aluminum due to the performance of the dipole drive-in process 260 (see FIG. 3), but the gate dielectric layers 230A-230D are not doped. Had the aluminum-free conductive layers 300A-300H not been formed, undesirable diffusion of aluminum may occur between the gate dielectric layers 230E-230H and the work function metal layer of the metal gate electrode layer 350. Such an undesirable diffusion could lead to a lower (and possibly insufficient) difference in aluminum content between the NFET of the vertical stack 210 (i.e., the counterpart NFET) and the NFET of the vertical stack 211 (i.e., the drive-in NFET). In turn, this could lead to a lower difference between the intended threshold voltages that should be achieved by the NFET of the vertical stack 210 and the NFET of the vertical stack 211, which will degrade device performance. The aluminum-free conductive layer 300A-300H herein prevent such an undesirable diffusion, and therefore the differences in aluminum content (and also in the intended threshold voltages) can still be maintained.

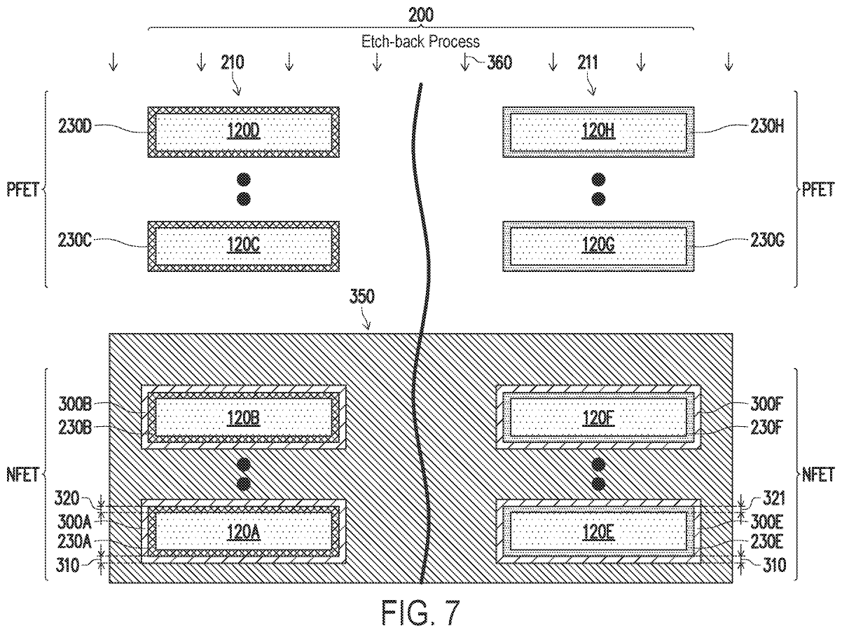

Referring now to FIG. 7, an etch-back process 360 is performed to the IC device 200. The etch-back process 360 etches back the metal gate electrode layer 350 for the PFETs, while a portion of the metal gate electrode layer 350 still remains over the aluminum-free conductive layers 300A, 300B, 300E, and 300F of the NFETs. The etch-back process 360 also etches away portions of the aluminum-free conductive layers 300C, 300D, 300G, and 300H of the PFETs, so that the gate dielectric layers 230C, 230D, 230G, and 230H are exposed.

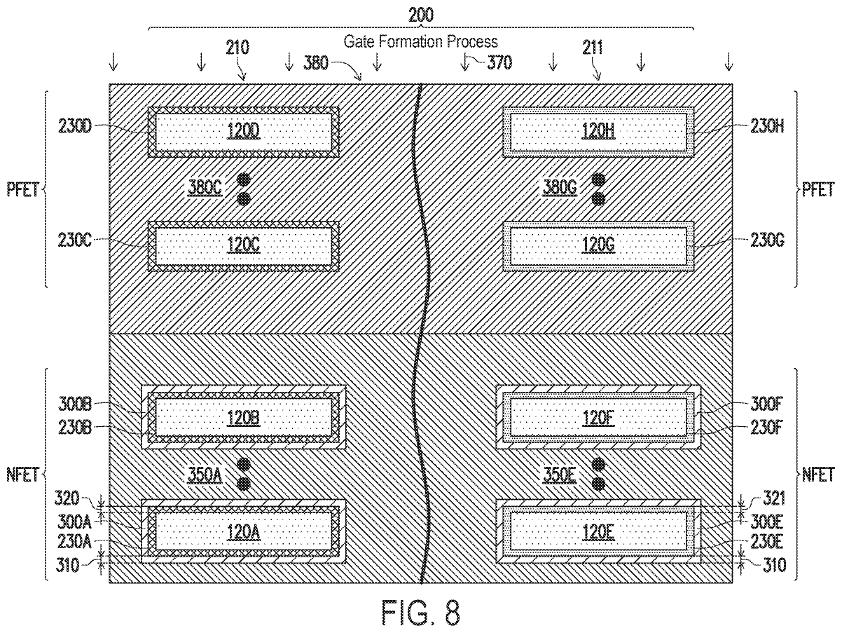

Referring now to FIG. 8, a gate formation process 370 is performed to the IC device 200 to form a metal gate electrode layer 380 for the PFETs in both the vertical stacks 210 and 211. For example, the metal gate electrode layer 380 is formed by one or more deposition processes, such as ALD, CVD, or PVD, and it circumferentially surrounds (e.g., in 360 degrees) each of the gate dielectric layers 230C, 230D, 230G, and 230H. The metal gate electrode layer 380 contains a p-type work function metal layer to tune a threshold voltage of the PFET of the vertical stack 210 and the PFET of the vertical stack 211. A fill metal layer is also formed over the work function metal layer and may serve as a main conductive portion of the gate electrode. In some embodiments, the fill metal layer may include titanium (Ti), tungsten (W), tantalum (Ta), copper (Cu), cobalt (Co), etc.

At this stage of fabrication, the following transistors are formed: a counterpart NFET (the NFET of the vertical stack 210), a counterpart PFET (the PFET of the vertical stack 210), a drive-in NFET (the NFET of the vertical stack 211), and a drive-in PFET (the PFET of the vertical stack 211). The threshold voltage of the counterpart NFET is tuned by a combination of the following components: the n-type work function metal layer of the metal gate electrode layer 350A, the undoped gate dielectric layer 230A and 230B, and the aluminum-free conductive layers 300A and 300B. The threshold voltage of the drive-in NFET is tuned by a combination of the following components: the n-type work function metal layer of the metal gate electrode layer 350E, the p-type doped gate dielectric layer 230E and 230F, and the aluminum-free conductive layers 300E and 300F. The threshold voltage of the counterpart PFET is tuned by a combination of the following components: the p-type work function metal layer of the metal gate electrode layer 380C, and the undoped gate dielectric layer 230C and 230D. The threshold voltage of the drive-in PFET is tuned by a combination of the following components: the p-type work function metal layer of the metal gate electrode layer 380G, and the p-type doped gate dielectric layer 230G and 230H.

These transistors (along with their distinct structural arrangements of the respective components) are formed as an inherent result of the fabrication processes of FIGS. 2-8 being performed herein. For example, the disposition of the aluminum-free conductive layers 300A-300B and 300E-300F between the gate electrodes 350A/350B and the gate dielectric layers 120A-120B and 120E-120F is an inherent result of the performance of the deposition process 280 (see FIG. 5, used to form the aluminum-free conductive layers 300A-300B and 300E-300F), followed by the gate formation process 340 (see FIG. 6) and the etch-back process 360 (which removes the aluminum-free conductive layers 300C-300D and 300G-300H from the PFETs).

Note that although aluminum is used herein as an example p-type dipole material, it is not intended to be limiting unless otherwise claimed. In other embodiments where the p-type dipole material is another element that is not aluminum, then the layers 300A-300H may be implemented as conductive layer that is free of that other non-aluminum element as well.

FIGS. 2-8 correspond to the process flow of a first embodiment of the present disclosure. FIGS. 9-15 correspond to the process flow of a second embodiment of the present disclosure. For reasons of simplicity, similar processes and/or components will be labeled the same throughout FIGS. 2-15.

Referring now to FIG. 9, the gate dielectric layers 230A-230H are formed to wrap around the channel components 120A-120H, respectively, of the vertical stacks 210 and 211. The dipole layer formation process 240 is performed to form the p-dipole dopant source layers 250E-250H to wrap around the gate dielectric layers 230E-230H, respectively.

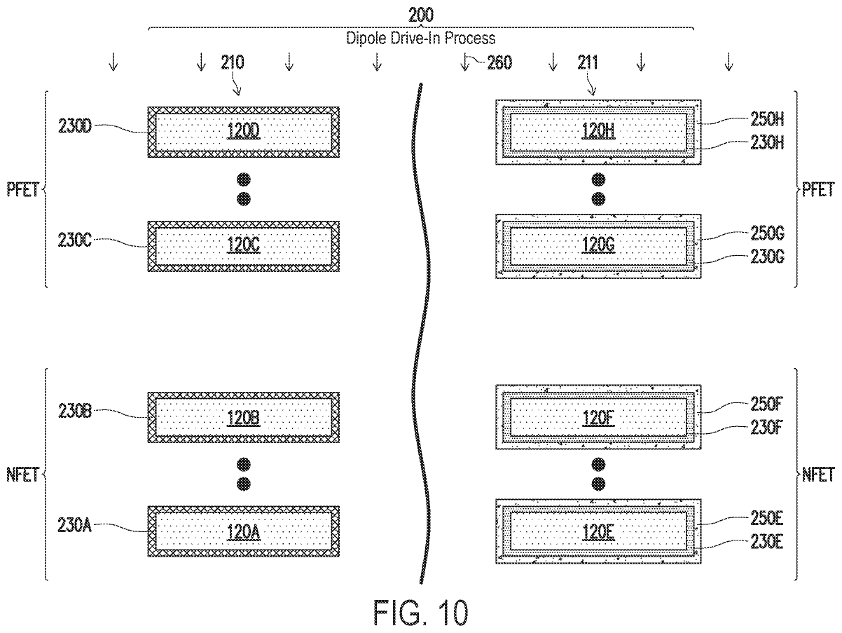

Referring now to FIG. 10, the dipole drive-in process 260 is performed to the IC device 200 to drive the atoms (e.g., aluminum atoms) from the p-dipole dopant source layers 250E-250H into the gate dielectric layers 230E-230H, respectively. The gate dielectric layers 230E-230H therefore become p-type doped (e.g., doped with aluminum) gate dielectric layers as a result of the dipole drive-in process 260 being performed.

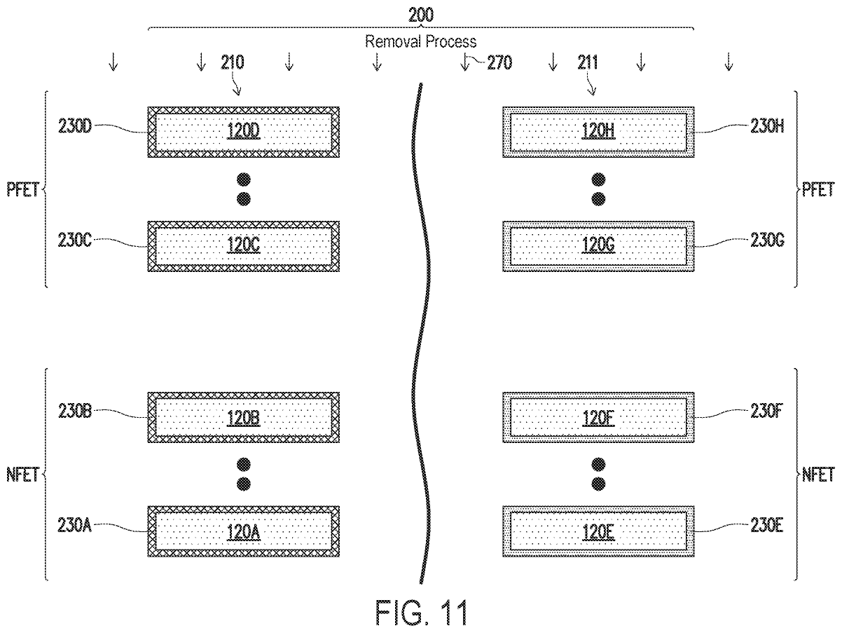

Referring now to FIG. 11, the removal process 270 is performed to the IC device 200 to remove the remaining portions of the p-dipole dopant source layers 250E-250H. Up to this point, the fabrication processes performed for the second embodiment are substantially the same as the fabrication processes performed for the first embodiment of the present disclosure.

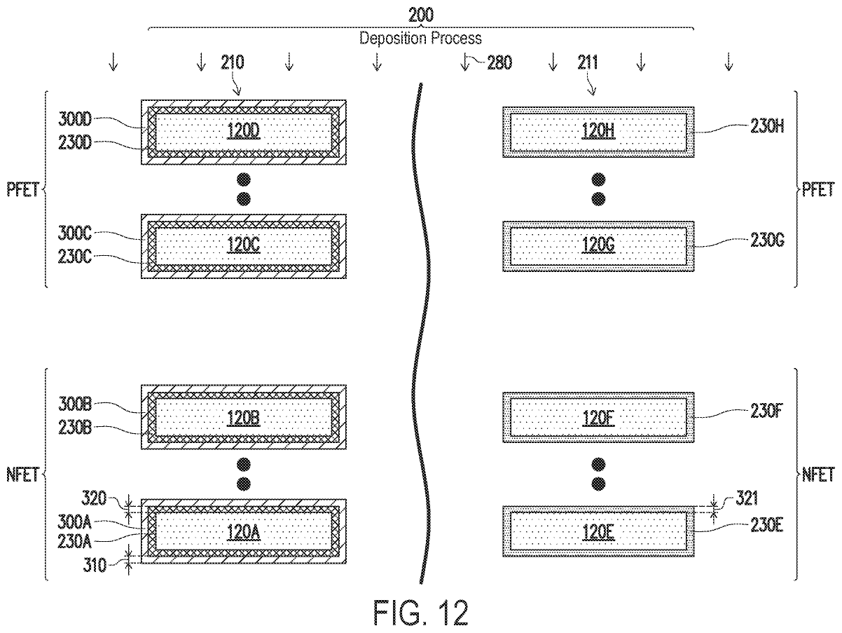

Referring now to FIG. 12, the deposition process 280 is performed to the IC device to form aluminum-free conductive layers. However, unlike the first embodiment, the deposition process 280 deposits the aluminum-free conductive layers 300A-300D for just the NFET and the PFET of the vertical stack 210 (i.e., the counterpart device), but no aluminum-free conductive layers are deposited for the NFET or the PFET of the vertical stack 211. In other words, the aluminum-free conductive layers 300A-300D are circumferentially formed around the gate dielectric layers 230A-230D, respectively, while the gate dielectric layers 230E-230H remain exposed after the performance of the deposition process 280.

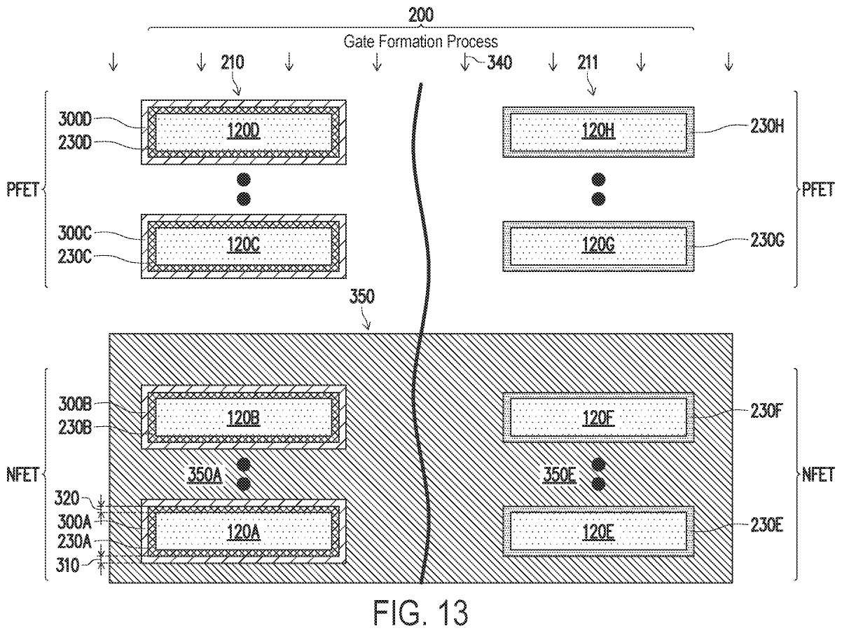

Referring now to FIG. 13, the gate formation process 340 is performed to the IC device 200 to form the gate electrode layer 350. Unlike the first embodiment, the gate formation process 340 forms the metal gate electrode layers 350A and 350E over just the NFETs of both the counterpart device and the drive-in device, respectively, but not over the PFET of the counterpart device or the PFET of the drive-in device. As discussed above, the metal gate electrode layers 350A and 350E (which may not be in direct contact with one another) may each contain an n-type work function metal layer configured to tune the threshold voltages of the NFETs of the counterpart device and the drive-in device.

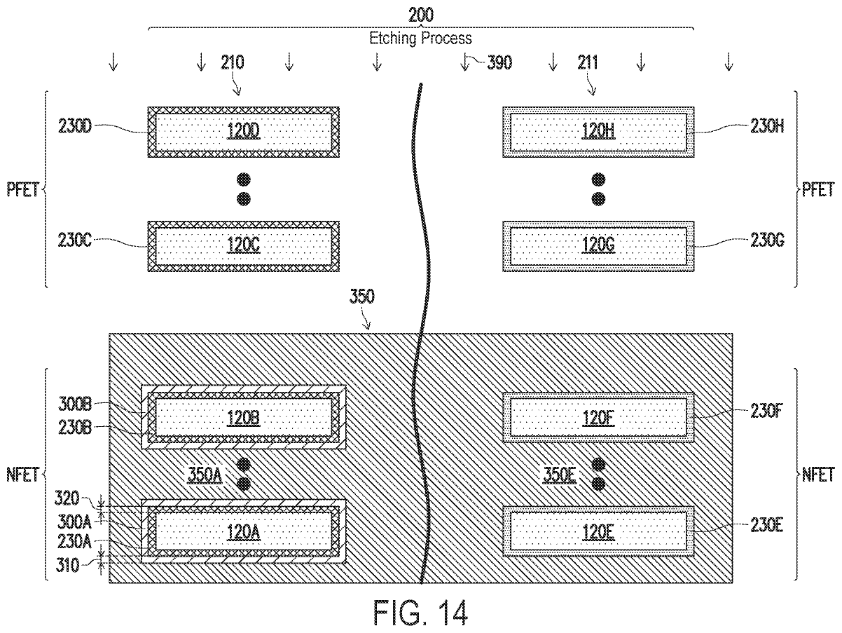

Referring now to FIG. 14, an etching process 390 is performed to remove the aluminum-free conductive layers 300C and 300D of the PFETs. The etching process 390 is configured to have an etching selectivity between the materials of the aluminum-free conductive layers 300C-300D and the materials of the gate dielectric layers 230C-230D and 230G-230H or the materials of the gate electrode layer 350A-350E. For example, the aluminum-free conductive layers 300C-300D are etched away at a substantially faster rate than the gate dielectric layers 230C-230D and 230G-230H or the materials of the gate electrode layer 350A-350E. As a result, the gate dielectric layers 230C-230D and 230G-230H and the gate electrode layer 350A-350E still remain (and are exposed) after the performance of the etching process 390.

Referring now to FIG. 15, the gate formation process 370 is performed to the IC device 200 to form the gate electrode layer 380. As is the case for the first embodiment, the gate formation process 370 forms the gate electrode layers 380C and 380G over just the PFETs of both the counterpart device and the drive-in device. As discussed above, the metal gate electrode layers 380C and 380G (which may not be in direct contact with one another) may each contain a p-type work function metal layer configured to tune the threshold voltages of the PFETs of the counterpart device and the drive-in device.

At this stage of fabrication, the following transistors are formed: a counterpart NFET (the NFET of the vertical stack 210), a counterpart PFET (the PFET of the vertical stack 210), a drive-in NFET (the NFET of the vertical stack 211), and a drive-in PFET (the PFET of the vertical stack 211). The threshold voltage of the counterpart NFET is tuned by a combination of the following components: the n-type work function metal layer of the metal gate electrode layer 350A, the undoped gate dielectric layer 230A and 230B, and the aluminum-free conductive layers 300A and 300B. The threshold voltage of the drive-in NFET is tuned by a combination of the following components: the n-type work function metal layer of the metal gate electrode layer 350E, the p-type doped gate dielectric layer 230E and 230F. Note that unlike the first embodiment illustrated in FIG. 8, the threshold voltage of the drive-in NFET is tuned without the aluminum-free conductive layers 300E and 300F in the second embodiment. Meanwhile, the threshold voltage of the counterpart PFET is tuned by a combination of the following components: the p-type work function metal layer of the metal gate electrode layer 380C, and the undoped gate dielectric layer 230C and 230D. The threshold voltage of the drive-in PFET is tuned by a combination of the following components: the p-type work function metal layer of the metal gate electrode layer 380G, and the p-type doped gate dielectric layer 230G and 230H.

These transistors (along with their distinct structural arrangements of the respective components) are formed as an inherent result of the fabrication processes of FIGS. 9-15 being performed herein. For example, the disposition of the aluminum-free conductive layers 300A-300B between the gate electrode 350A and the gate dielectric layers 120A-120B is an inherent result of the performance of the deposition process 280 (see FIG. 12, used to form the aluminum-free conductive layers 300A-300B and 300C-300D), followed by the gate formation process 340 (see FIG. 13) and the etching process 390 (see FIG. 14, which removes the aluminum-free conductive layers 300C-300D from the PFETs).

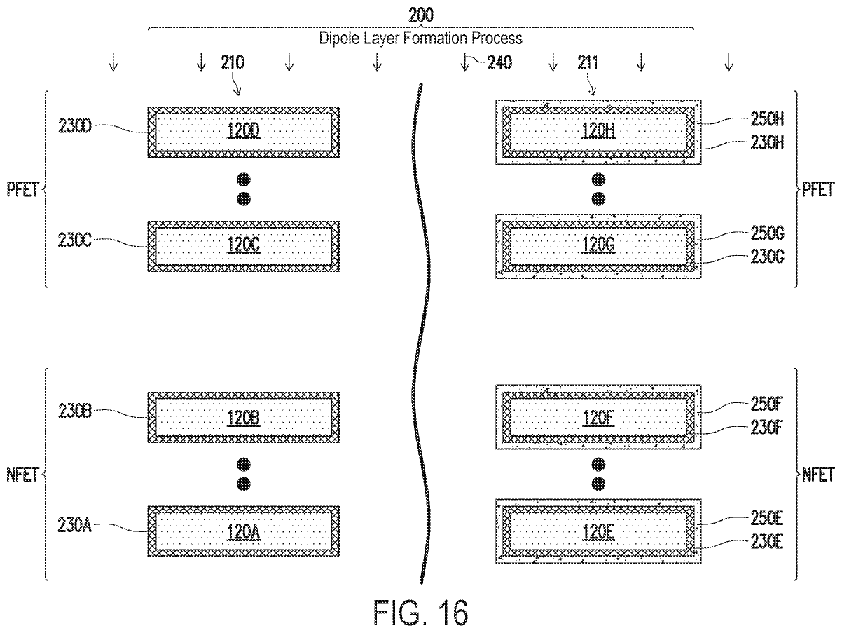

As discussed above, FIGS. 2-8 and FIGS. 9-15 correspond to the process flow of a first embodiment and a second embodiment of the present disclosure, respectively. FIGS. 16-22 correspond to the process flow of a third embodiment of the present disclosure. For reasons of simplicity, similar processes and/or components will be labeled the same throughout FIGS. 2-22.

Referring now to FIG. 16, the gate dielectric layers 230A-230H are formed to wrap around the channel components 120A-120H, respectively, of the vertical stacks 210 and 211. The dipole layer formation process 240 is performed to form the p-dipole dopant source layers 250E-250H to wrap around the gate dielectric layers 230E-230H, respectively.

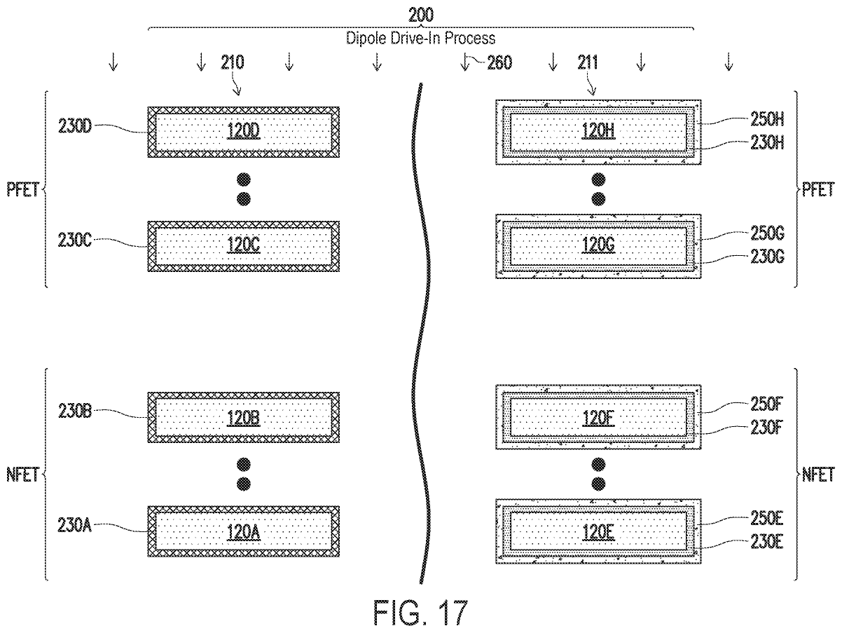

Referring now to FIG. 17, the dipole drive-in process 260 is performed to the IC device 200 to drive the atoms (e.g., aluminum atoms) from the p-dipole dopant source layers 250E-250H into the gate dielectric layers 230E-230H, respectively. The gate dielectric layers 230E-230H therefore become p-type doped (e.g., doped with aluminum) gate dielectric layers as a result of the dipole drive-in process 260 being performed.

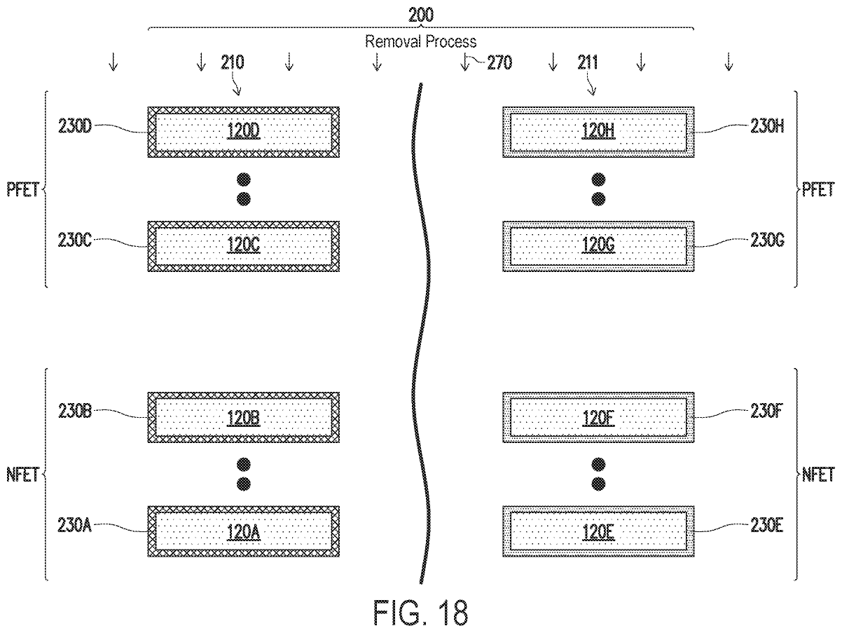

Referring now to FIG. 18, the removal process 270 is performed to the IC device 200 to remove the remaining portions of the p-dipole dopant source layers 250E-250H. Up to this point, the fabrication processes performed for the third embodiment are substantially the same as the fabrication processes performed for the first embodiment and the second embodiment of the present disclosure.

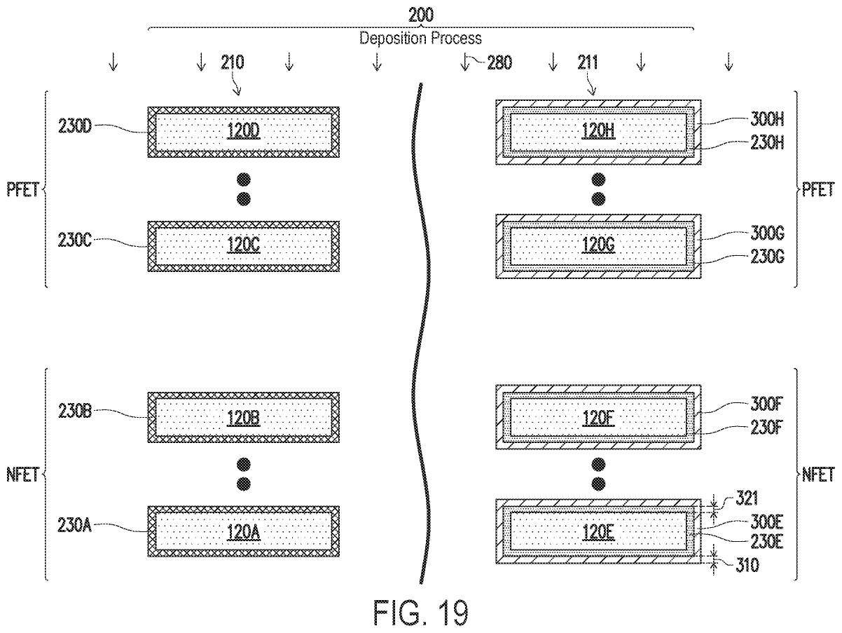

Referring now to FIG. 19, the deposition process 280 is performed to the IC device to form aluminum-free conductive layers. However, unlike the first or the second embodiment, the deposition process 280 deposits the aluminum-free conductive layers 300E-300H for just the NFET and the PFET of the vertical stack 211 (i.e., the drive-in device), but no aluminum-free conductive layers are deposited for the NFET or the PFET of the vertical stack 210. In other words, the aluminum-free conductive layers 300E-300H are circumferentially formed around the gate dielectric layers 230E-230H, respectively, while the gate dielectric layers 230A-230D remain exposed after the performance of the deposition process 280.

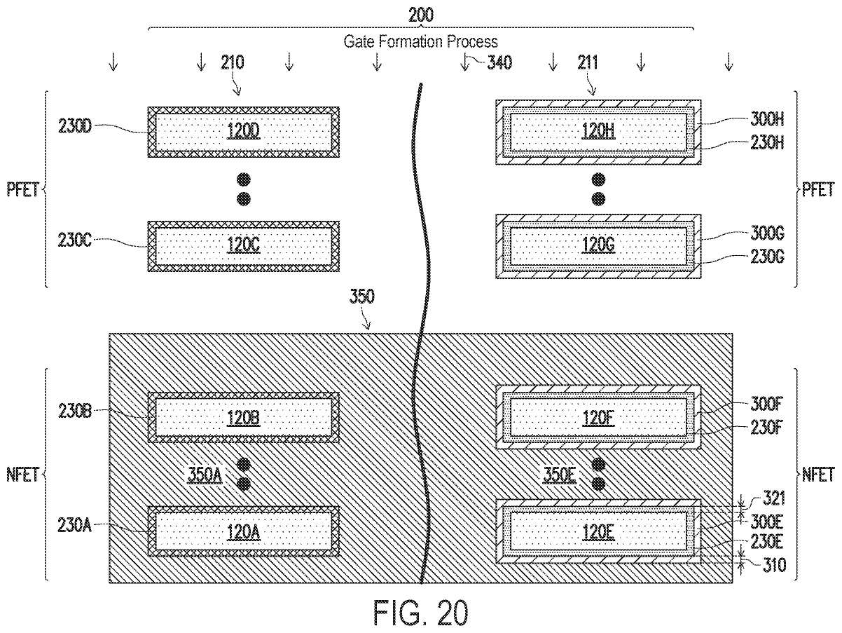

Referring now to FIG. 20, the gate formation process 340 is performed to the IC device 200 to form the gate electrode layer 350. Like the second embodiment (but not the first embodiment), the gate formation process 340 forms the metal gate electrode layers 350A and 350E over just the NFETs of both the counterpart device and the drive-in device, but not over the PFET of the counterpart device or the PFET of the drive-in device. As discussed above, the metal gate electrode layers 350A and 350E (which may not be in direct contact with one another) may each contain an n-type work function metal layer configured to tune the threshold voltages of the NFETs of the counterpart device and the drive-in device.

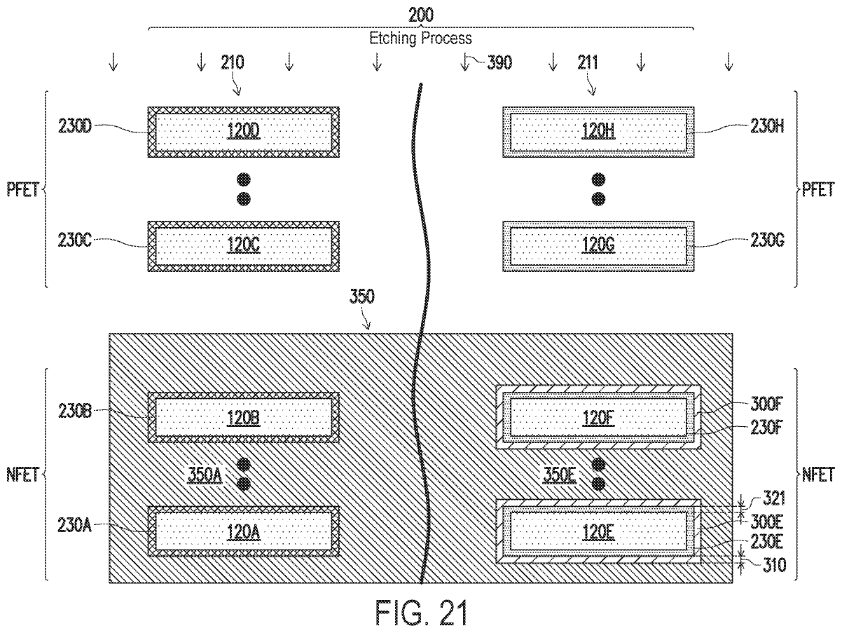

Referring now to FIG. 21, an etching process 390 is performed to remove the aluminum-free conductive layers 300G and 300H of the PFETs. The etching process 390 is configured to have an etching selectivity between the materials of the aluminum-free conductive layers 300G-300H and the materials of the gate dielectric layers 230C-230D and 230G-230H or the materials of the gate electrode layer 350A-350E. For example, the aluminum-free conductive layers 300G-300H are etched away at a substantially faster rate than the gate dielectric layers 230C-230D and 230G-230H or the materials of the gate electrode layer 350A-350E. As a result, the gate dielectric layers 230C-230D and 230G-230H and the gate electrode layer 350A-350E still remain (and are exposed) after the performance of the etching process 390.

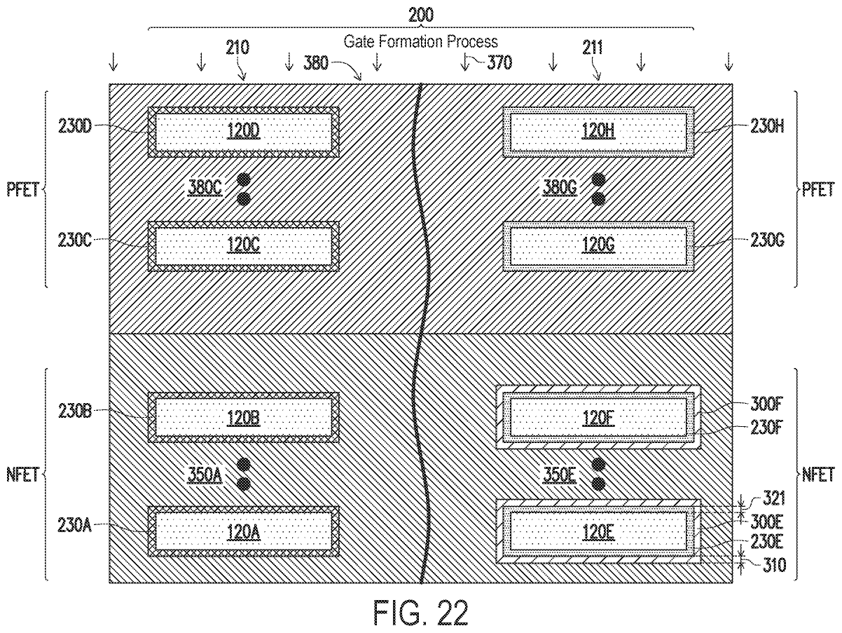

Referring now to FIG. 22, the gate formation process 370 is performed to the IC device 200 to form the gate electrode layer 380. As is the case for the first embodiment, the gate formation process 370 forms the gate electrode layers 380C and 380G over just the PFETs of both the counterpart device and the drive-in device. As discussed above, the metal gate electrode layers 380C and 380G (which may not be in direct contact with one another) may each contain a p-type work function metal layer configured to tune the threshold voltages of the PFETs of the counterpart device and the drive-in device.

At this stage of fabrication, the following transistors are formed: a counterpart NFET (the NFET of the vertical stack 210), a counterpart PFET (the PFET of the vertical stack 210), a drive-in NFET (the NFET of the vertical stack 211), and a drive-in PFET (the PFET of the vertical stack 211). The threshold voltage of the counterpart NFET is tuned by a combination of the following components: the n-type work function metal layer of the metal gate electrode layer 350A, the undoped gate dielectric layer 230A and 230B. Note that unlike the first embodiment illustrated in FIG. 8 or the second embodiment illustrated in FIG. 15, the threshold voltage of the counterpart NFET is tuned without the aluminum-free conductive layers 300A and 300B in the third embodiment. The threshold voltage of the drive-in NFET is tuned by a combination of the following components: the n-type work function metal layer of the metal gate electrode layer 350E, the p-type doped gate dielectric layer 230E and 230F, and the aluminum-free conductive layers 300E and 300F. Meanwhile, the threshold voltage of the counterpart PFET is tuned by a combination of the following components: the p-type work function metal layer of the metal gate electrode layer 380C, and the undoped gate dielectric layer 230C and 230D. The threshold voltage of the drive-in PFET is tuned by a combination of the following components: the p-type work function metal layer of the metal gate electrode layer 380G, and the p-type doped gate dielectric layer 230G and 230H.

These transistors (along with their distinct structural arrangements of the respective components) are formed as an inherent result of the fabrication processes of FIGS. 16-22 being performed herein. For example, the disposition of the aluminum-free conductive layers 300E-300F between the gate electrode 350E and the gate dielectric layers 120E-120F is an inherent result of the performance of the deposition process 280 (see FIG. 19, used to form the aluminum-free conductive layers 300E-300F and 300G-300H), followed by the gate formation process 340 (see FIG. 20) and the etching process 390 (see FIG. 21, which removes the aluminum-free conductive layers 300G-300H from the PFETs).

It is understood that although FIGS. 2-22 illustrate PFETs over NFETs vertically, they may be switched in other embodiments. It is also understood that although the aluminum-free conductive layers are implemented for the bottom transistors (e.g., the NFETs herein), the aluminum-free conductive layers may also be implemented for the top transistors in embodiments where the NFETs are implemented vertically over the PFETs.

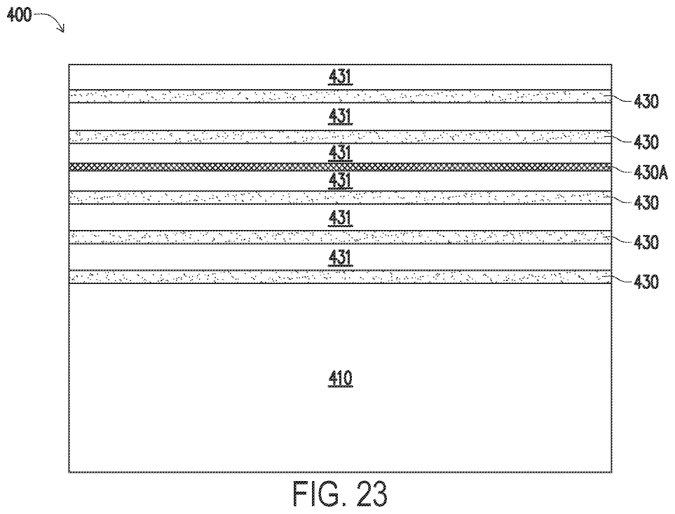

It is also understood that the various aspects of the present disclosure (e.g., implementing the aluminum-free conductive layers to block aluminum diffusion) may apply not to just GAA and FinFET devices, but also to complementary field effect transistors (CFET). In that regard, FIGS. 23-19 are a series of diagrammatic fragmentary cross-sectional side views illustrating an example process flow to fabricate an example CFET 400 according to embodiments of the present disclosure.

Referring to FIG. 23, the CFET 400 includes a substrate 410, which may be an embodiment of the substrate 110 discussed above. In some embodiments, the substrate 410 may be a silicon substrate. A plurality of alternating semiconductor layers 430 and 431 are formed over the substrate 410. In some embodiments, the semiconductor layers 430 include silicon germanium (SiGe), and the semiconductor layers 431 include silicon (Si). Note that one of the semiconductor layers 430A, while still having a SiGe material composition, contains a higher content or concentration of SiGe than the rest of the semiconductor layers 430. As will be discussed below in more detail, this semiconductor layer 430A will be replaced with a channel isolation structure in a subsequent process. It is understood that the number of semiconductor layers 430 and 431 need not be constrained to the ones illustrated in FIG. 23, and that any other suitable number of semiconductor layers 430 and 431 may be implemented in other embodiments.

Portions of the semiconductor layers 431 are patterned into nano-structure channels 431, for example, as nano-sheets, nano-tubes, nano-wires, nano-bars, etc. Dummy gate structures 440 are formed over the uppermost one of the nano-structure channels 431. In some embodiments, the dummy gate structures 440 may include a polysilicon dummy gate electrode. Each dummy gate structure 440 may be patterned by one or more hard mask layers 450, which may include one or more dielectric materials. Gate spacers 460 are formed on sidewalls of the dummy gate structure 440. The gate spacers 460 may also include a suitable dielectric material. In some embodiments, each of the gate spacers 460 may include a plurality of gate spacer layers, but this is not specifically illustrated herein for reasons of simplicity. Note that a plurality of openings 470 are formed to divide the components of the CFET 400 into separate stacks, where each stack has its own dummy gate structure 440.

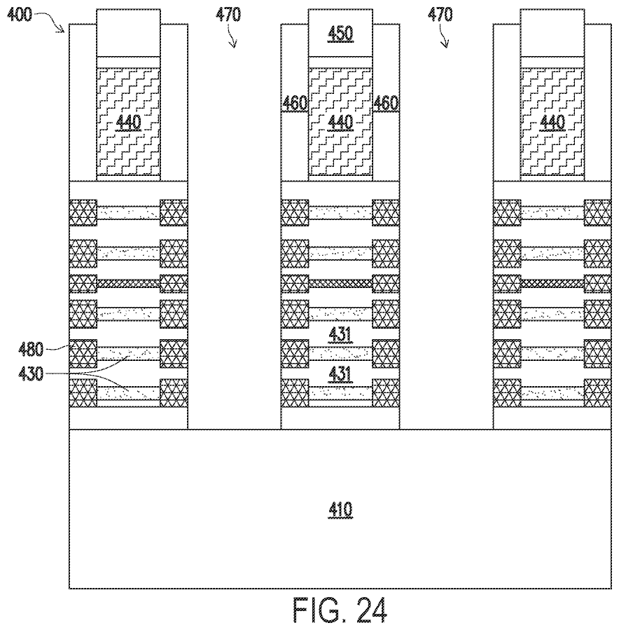

Still referring to FIG. 24, inner spacers 480 are also formed between the nano-structure channels 431 vertically. The inner spacers 480 are also disposed at opposite end portions of each of the remaining portions of the semiconductor layers 430. The inner spacers 480 may also include a suitable dielectric material.

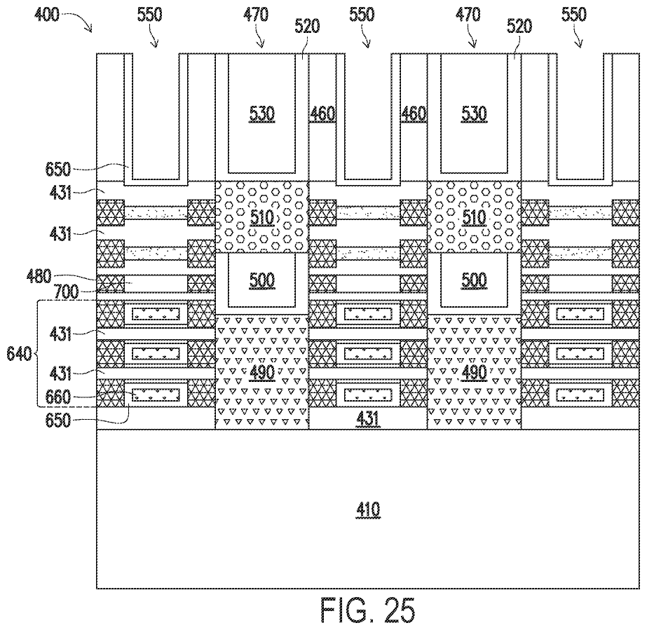

Referring now to FIG. 25, source/drain regions 490 and source/drain regions 510 are formed in the openings 470 and over isolation structures 500. As used herein, the source/drain region 490, or “S/D region,” may refer to a source or a drain of a transistor device. It may also refer to a region that provides a source and/or drain for multiple transistor devices. The source/drain regions 490 and the source/drain regions 510 may each directly abut the side surfaces one or more of the nano-structure channels 431 of the top device of the CFET 400, as well as side surfaces of one or more of the inner spacers 480 of the top device of the CFET 400. The source/drain regions 490 are components of the bottom device of the CFET 400. As such, the source/drain regions 490 may also be referred to as bottom source/drain regions 490. The source/drain regions 510 are components of the top device of the CFET 400. As such, the source/drain regions 510 may also be referred to as top source/drain regions 510. Note that the isolation structures 500—which may include a dielectric liner layer (e.g., an etching-stop layer) and a dielectric component formed over the dielectric liner layer—are disposed between the bottom source/drain regions 490 and the top source/drain regions 510 and provide electrical isolation therebetween. The dielectric liner and the dielectric component may include different types of dielectric materials in some embodiments.

An etching stop layer 520 is formed over the top source/drain regions 510 in the openings 470. An interlayer dielectric (ILD) 530 is formed over in the opening 470 over the etching stop layer 520. The ILD 530 may also be referred to as an ILDO. The etching stop layer 520 and the ILD 530 may include different types of dielectric materials. The etching stop layer 520 and the ILD 530 may be planarized by a chemical mechanical polishing (CMP) process to flatten their upper surfaces.

Still referring to FIG. 25, the dummy gate structures 440 are removed, for example, via one or more etching processes. The etching processes are configured to have sufficient etching selectivity between the materials of the dummy gate structures 440 (e.g., polysilicon) and the gate spacers 460, the etching stop layer 520, and the ILD 530, which may all contain dielectric materials. As such, the removal of the dummy gate structures 440 does not substantially impact the gate spacers 460, the etching stop layer 520, and the ILD 530. Therefore, openings 550 may be formed by the removal of the dummy gate structures 440.

The semiconductor layers 430 (e.g., containing SiGe) are also removed, for example, using one or more etching processes. Thereafter, gate structures 640 for the bottom device of the CFET 400 are formed. For example, the gate structures 640 may include gate dielectric structures 650 and gate electrodes 660 are formed to replace the removed semiconductor layers 430 and the removed dummy gate structures 440 for the bottom device. Note that portions of the gate dielectric structure 650 may also serve as the gate dielectric structures of the top tier device of the CFET 400. However, the gate electrodes of the top device of the CFET 400 are not formed yet. For example, one or more etch back processes may be performed to etch back the gate electrodes 660 that are located in the top device regions, such that empty spaces occupy (at this time) what will eventually become the gate electrodes of the top device of the CFET.

As shown in FIG. 25, a channel isolation structure 700 is formed between each pair of the bottom device and the top device of the CFET 400. The channel isolation structure 700 is formed in place of the removed semiconductor layer 430A, which has a higher SiGe content, as discussed above. The channel isolation structure 700 may include a dielectric material, and along with the inner spacers 480, it may help provide electrical isolation between the nano-structure channels 431 of the bottom device and the nano-structure channels 431 of the top device of the CFET 400.

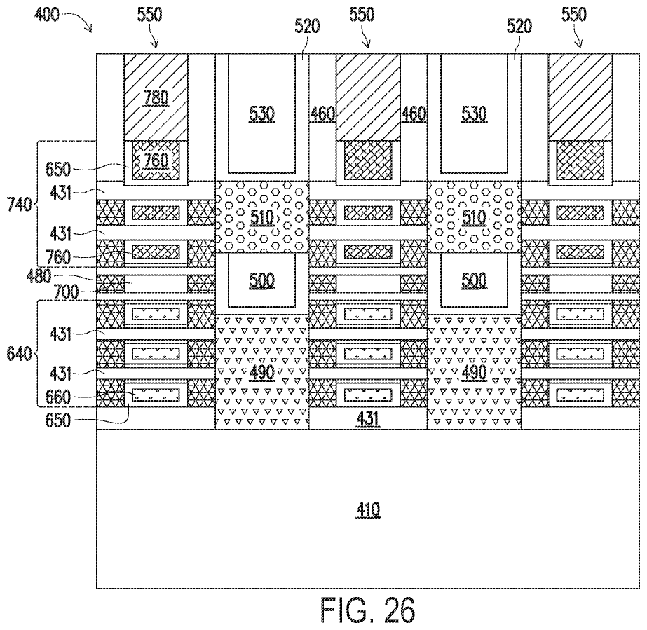

Referring now to FIG. 26, gate structures 740 for the top device of the CFET 400 are formed. The gate structures 740 may include gate dielectric structures 650 (formed previously in FIG. 25) and gate electrodes 760, which collectively fill the openings that were formed as a result of the removal of the semiconductor layers 430 and the removed dummy gate structures 440 of the top device.

The processes discussed above with reference to FIGS. 2-22 may be used to form the gate structures 640 and/or 740. For example, the gate dielectric structures 650 may be implemented as an embodiment of one of the gate dielectric layers 230A-230H discussed above with reference to FIGS. 2-22, which may be undoped or doped (e.g., doped with aluminum), depending on whether the CFET 400 herein is supposed to be a counterpart device or a dipole drive-in device. The gate electrode layers 660/760 may also be implemented as an embodiment of the metal gate electrode layers 350 or 380 discussed above. In addition, although it is not specifically illustrated herein for reasons of simplicity, it is understood that the aluminum-free conductive layer 300A/B or aluminum-free conductive layer 300E/F discussed above may be implemented between the gate dielectric structures 650 and the gate electrodes 660, or between the gate dielectric structures 650 and the gate electrodes 760, depending on whether the bottom device or the top device is the NFET.

Still referring to FIG. 26, a self-aligned contact (SAC) 780 may also be formed over the gate structures 740. The SAC 780 completely fill the openings 550 that were formed as a result of the removal of the dummy gate structures 440. In some embodiments, the SAC 780 may include a dielectric material.

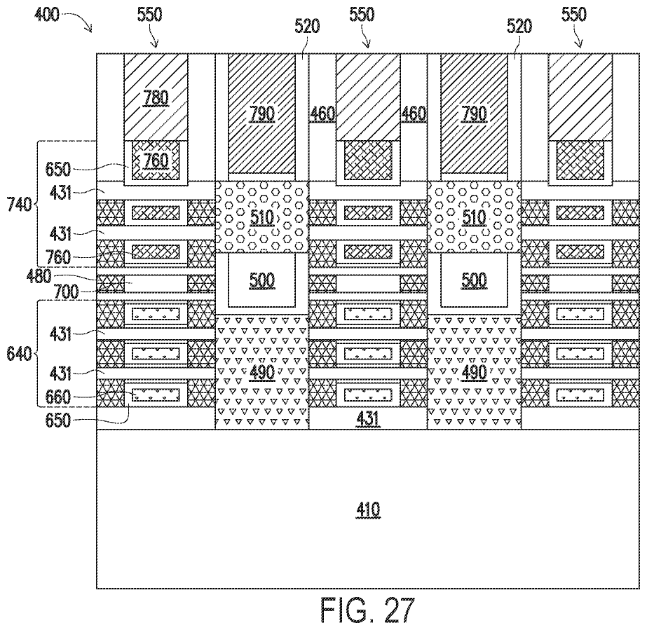

Referring now to FIG. 27, the ILD 530 and portions of the etching stop layer 520 are removed, such that the upper surfaces of the source/drain regions 510 are exposed. Thereafter, source/drain contacts 790 are formed over the source/drain regions 510 to provide electrical connectivity to the source/drain regions 510. In some embodiments, a silicide layer may be formed between the source/drain regions 510 and the source/drain contacts 790 to reduce the electrical resistance of the source/drain contacts 790.

It is understood that additional processes may be performed to continue the fabrication of the CFET 400. for example, conductive gate contacts may be formed (e.g., extending vertically through the SAC 780) to provide electrical connectivity to the gate structures 740. Packaging processes may also be formed to continue the packaging of the CFET 400.

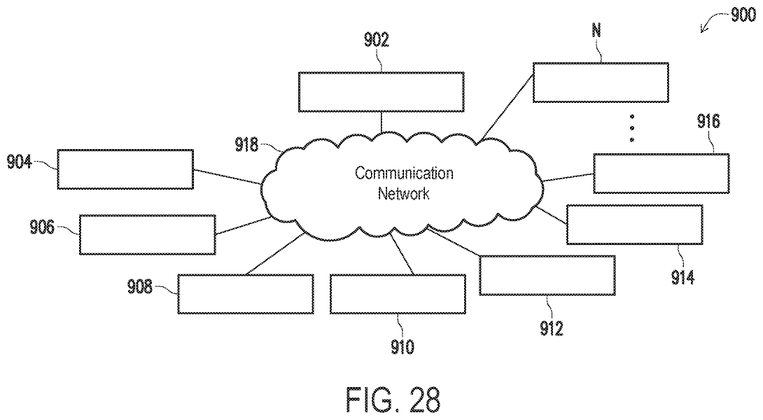

FIG. 28 illustrates an integrated circuit fabrication system 900 that may be used to perform the fabrication processes discussed above with reference to FIGS. 2-22, and/or to fabricate the CFET 400, according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the gate spacers of an SRAM device; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

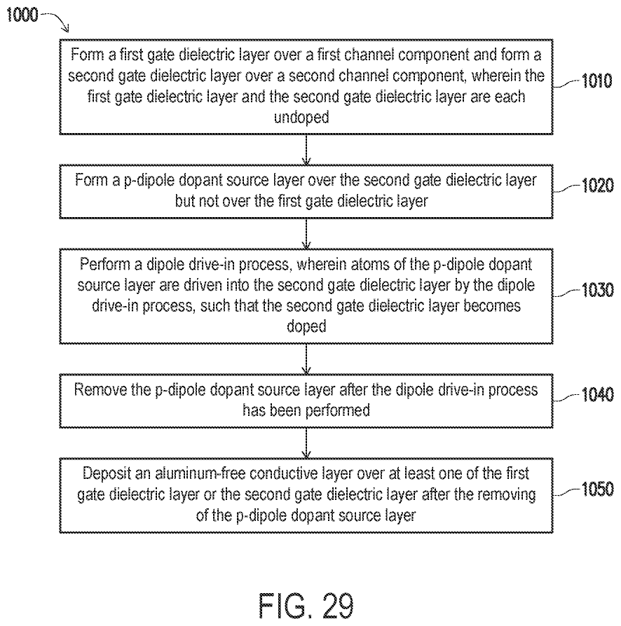

FIG. 29 is a flowchart of a method 1000 of fabricating a semiconductor device according to various aspects of the present disclosure. The method 1000 includes a step 1010 to form a first gate dielectric layer over a first channel component and to form a second gate dielectric layer over a second channel component. The first gate dielectric layer and the second gate dielectric layer are each undoped.

The method 1000 includes a step 1020 to form a p-dipole dopant source layer over the second gate dielectric layer but not over the first gate dielectric layer.

The method 1000 includes a step 1030 to perform a dipole drive-in process. Atoms of the p-dipole dopant source layer are driven into the second gate dielectric layer by the dipole drive-in process, such that the second gate dielectric layer becomes doped.

The method 1000 includes a step 1040 to remove the p-dipole dopant source layer after the dipole drive-in process has been performed.

The method 1000 includes a step 1050 to deposit an aluminum-free conductive layer over at least one of the first gate dielectric layer or the second gate dielectric layer after the removing of the p-dipole dopant source layer.

In some embodiments, the step 1050 comprises depositing a first aluminum-free conductive layer that circumferentially wraps around the first gate dielectric layer in a cross-sectional side view and depositing a second aluminum-free conductive layer that circumferentially wraps around the second gate dielectric layer in the cross-sectional side view. In some embodiments, a gate electrode layer is formed that circumferentially wraps around both the first aluminum-free conductive layer and the second aluminum-free conductive layer in the cross-sectional side view, where the gate electrode layer contains an n-type work function metal.

In some embodiments, the step 1050 comprises depositing the aluminum-free conductive layer that circumferentially wraps around the first gate dielectric layer but not over the second gate dielectric layer in a cross-sectional side view. In some embodiments, a gate electrode layer is formed that circumferentially wraps around both the aluminum-free conductive layer and the second gate dielectric layer in the cross-sectional side view, where the gate electrode layer contains an n-type work function metal.

In some embodiments, the step 1050 comprises depositing the aluminum-free conductive layer that circumferentially wraps around the second gate dielectric layer but not over the first gate dielectric layer in a cross-sectional side view. In some embodiments, a gate electrode layer is formed that circumferentially wraps around both the aluminum-free conductive layer and the first gate dielectric layer in the cross-sectional side view, where the gate electrode layer contains an n-type work function metal.

In some embodiments, the step 1050 comprises depositing a titanium nitride layer as the aluminum-free conductive layer.

In some embodiments, the first channel component and the first gate dielectric layer are portions of a first n-type transistor, and the second channel component and the second gate dielectric layer are portions of a second n-type transistor. In some embodiments, a first p-type transistor is formed over the first n-type transistor, a second p-type transistor is formed over the second n-type transistor, a third gate dielectric layer is formed over a third channel component of a first p-type transistor, and a fourth gate dielectric layer is formed over a fourth channel component of the second p-type transistor.

It is understood that the method 1000 may include further steps performed before, during, or after the steps 1010-1050. For example, the method 1000 may include a step of forming an n-type metal gate electrode that circumferentially surrounds the first n-type transistor, the second n-type transistor, the first p-type transistor, and the second p-type transistor in a cross-sectional side view. The method 1000 may further include a step of removing portions of the n-type metal gate electrode that circumferentially surrounds the first p-type transistor and the second p-type transistor. The method 1000 may also include a step of forming a p-type metal gate electrode over a remaining portion of the n-type metal gate electrode. The p-type metal gate electrode circumferentially surrounds both the first p-type transistor and the second p-type transistor in the cross-sectional side view. As another example, the method 1000 may further include a step of forming an n-type metal gate electrode that circumferentially surrounds both the first n-type transistor and the second n-type transistor, but not the first p-type transistor or the second p-type transistor, in a cross-sectional side view. The method 1000 may also include a step of forming a p-type metal gate electrode that circumferentially surrounds both the first p-type transistor and the second p-type transistor in the cross-sectional side view. The p-type metal gate electrode is formed over the n-type metal gate electrode. For reasons of simplicity, other additional steps are not discussed herein in detail.

In summary, the present disclosure involves implementing an aluminum-free conductive layer between the gate dielectric layer and the metal gate electrode of NFET devices. The aluminum-free conductive layer may include a conductive material (other than aluminum) that is configured to block aluminum diffusion. In some embodiments, the aluminum-free conductive layer is implemented for both a dipole drive-in device and a counterpart device. In some other embodiments, the aluminum-free conductive layer is implemented for just the dipole drive-in device but not for the counterpart device. In yet other embodiments, the aluminum-free conductive layer is implemented for just the counterpart device but not for the dipole drive-in device. In some embodiments, the aluminum-free conductive layer is implemented for NFET devices but not for PFET devices that are formed in a same vertical stack as the NFET device, for example, as a part of a CFET.

The embodiments of the present disclosure offer advantages over conventional CFET devices. It is understood, however, that other embodiments may offer additional advantages, and not all advantages are necessarily disclosed herein, and that no particular advantage is required for all embodiments. One advantage is the reduction in aluminum diffusion. In more detail, aluminum is commonly used as a dipole material to provide the tuning of different threshold voltages for different transistors. However, n-type work function metal layers may also include aluminum. If a gate dielectric layer that is not intended to be doped with aluminum is in direct contact with an aluminum-containing n-type work function metal layer, then undesirable aluminum diffusion could occur between the gate dielectric layer and the n-type work function metal layer of the metal gate electrode. This undesirable diffusion could adversely interfere with the threshold voltage tuning, and/or lead to insufficient differences between threshold voltages between a drive-in transistor and a counterpart transistor. Here, the insertion of the aluminum-free conductive layer between the gate dielectric layers and the aluminum-containing metal gate electrode (e.g., the aluminum-containing work function metal layer) helps reduce or eliminate the undesirable aluminum diffusion. As a result, the devices fabricated according to the present disclosure can still achieve their intended tuning of threshold voltages, thereby improving device performance. Other advantages include compatibility with existing fabrication processes and the ease and low cost of implementation.

One aspect of the present disclosure pertains to a device. The device includes a first n-type transistor and a second n-type transistor. The first n-type transistor includes a first channel component, an undoped first gate dielectric layer disposed over the first channel component, and a first gate electrode disposed over the undoped first gate dielectric layer. The second n-type transistor includes a second channel component and a doped second gate dielectric layer disposed over the second channel component. The second gate dielectric layer is doped with a p-type dipole material. A second gate electrode is disposed over the second gate dielectric layer. At least one of the first n-type transistor or the second n-type transistor further includes an aluminum-free conductive layer. The aluminum-free conductive layer is disposed between the first gate dielectric layer and the first gate electrode or between the second gate dielectric layer and the second gate electrode.

Another aspect of the present disclosure pertains to a device. The device includes a first vertical stack of transistors. The first vertical stack of transistors includes a first n-type transistor and a first p-type transistor. The device includes a second vertical stack of transistors. The second vertical stack of transistors includes a second n-type transistor and a second p-type transistor. The first n-type transistor and the first p-type transistor include undoped gate dielectric layers. The second n-type transistor and the second p-type transistor include doped gate dielectric layers. At least one of the first n-type transistor or the second n-type transistor, but not the first p-type transistor or the second p-type transistor, is circumferentially surrounded by an aluminum-free conductive layer. An n-type metal gate electrode circumferentially surrounds the aluminum-free conductive layer.

Another aspect of the present disclosure pertains to a method. A first gate dielectric layer is formed over a first channel component, and a second gate dielectric layer is formed over a second channel component. The first gate dielectric layer and the second gate dielectric layer are each undoped. A p-dipole dopant source layer is formed over the second gate dielectric layer but not over the first gate dielectric layer. A dipole drive-in process is performed. Atoms of the p-dipole dopant source layer are driven into the second gate dielectric layer by the dipole drive-in process, such that the second gate dielectric layer becomes doped. The p-dipole dopant source layer is removed after the dipole drive-in process has been performed. An aluminum-free conductive layer is deposited over at least one of the first gate dielectric layer or the second gate dielectric layer after the removing of the p-dipole dopant source layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first n-type transistor that includes:
a first channel component;
a first gate dielectric layer disposed over the first channel component, wherein the first gate dielectric layer is undoped; and
a first gate electrode disposed over the first gate dielectric layer; and
a second n-type transistor that includes:
a second channel component;
a second gate dielectric layer disposed over the second channel component, wherein the second gate dielectric layer is doped with a p-type dipole material; and
a second gate electrode disposed over the second gate dielectric layer;
wherein at least one of the first n-type transistor or the second n-type transistor further includes an aluminum-free conductive layer, and wherein the aluminum-free conductive layer is disposed between the first gate dielectric layer and the first gate electrode or between the second gate dielectric layer and the second gate electrode.

2. The device of claim 1, wherein:
the first gate dielectric layer circumferentially wraps around the first channel component in a cross-sectional side view;
the first gate electrode circumferentially wraps around the first gate dielectric layer in the cross-sectional side view;
the second gate dielectric layer circumferentially wraps around the second channel component in the cross-sectional side view;
the second gate electrode circumferentially wraps around the second gate dielectric layer in the cross-sectional side view; and
the first gate electrode or the second gate electrode circumferentially wraps around the aluminum-free conductive layer in the cross-sectional side view.

3. The device of claim 1, wherein:
the first n-type transistor includes a first aluminum-free conductive layer between the first gate dielectric layer and the first gate electrode; and
the second n-type transistor includes a second aluminum-free conductive layer between the second gate dielectric layer and the second gate electrode.

4. The device of claim 1, wherein:
the first n-type transistor, but not the second n-type transistor, includes the aluminum-free conductive layer between the first gate dielectric layer and the first gate electrode; and
the second gate dielectric layer is in direct contact with the second gate electrode.

5. The device of claim 1, wherein:
the second n-type transistor, but not the first n-type transistor, includes the aluminum-free conductive layer between the second gate dielectric layer and the second gate electrode; and
the first gate dielectric layer is in direct contact with the first gate electrode.

6. The device of claim 1, wherein the aluminum-free conductive layer is also free of p-type materials.

7. The device of claim 1, wherein the aluminum-free conductive layer includes titanium nitride.

8. The device of claim 1, wherein:
the first gate dielectric layer has a first thickness;
the second gate dielectric layer has a second thickness;
the aluminum-free conductive layer has a third thickness;
a ratio between the third thickness and the first thickness is in a range between about 0.1:1 and about 5:1; and
a ratio between the third thickness and the second thickness is in a range between about 0.1:1 and about 5:1.

9. The device of claim 1, further comprising:
a first p-type transistor disposed over the first n-type transistor, wherein the first p-type transistor includes:
a third channel component;
a third gate dielectric layer disposed over the third channel component, wherein the third gate dielectric layer is undoped; and
a third gate electrode disposed over the third gate dielectric layer, wherein the third gate electrode is in direct contact with the third gate dielectric layer; and
a second p-type transistor disposed over the second n-type transistor, wherein the second p-type transistor includes:
a fourth channel component;
a fourth gate dielectric layer disposed over the fourth channel component, wherein the fourth gate dielectric layer is doped with the p-type dipole material; and
a fourth gate electrode disposed over the fourth gate dielectric layer, wherein the fourth gate electrode is in direct contact with the fourth gate dielectric layer.

10. A device, comprising:
a first vertical stack of transistors, wherein the first vertical stack of transistors includes a first n-type transistor and a first p-type transistor;
a second vertical stack of transistors, wherein the second vertical stack of transistors includes a second n-type transistor and a second p-type transistor;
wherein:
the first n-type transistor and the first p-type transistor include undoped gate dielectric layers;
the second n-type transistor and the second p-type transistor include doped gate dielectric layers;
at least one of the first n-type transistor or the second n-type transistor, is circumferentially surrounded by a conductive layer that is free of a dipole material; and
an n-type metal gate electrode circumferentially surrounds the conductive layer.

11. The device of claim 10, wherein:
the doped gate dielectric layers are doped with aluminum; and
the conductive layer is free of aluminum and contains titanium nitride.

12. The device of claim 10, wherein the first p-type transistor and the second p-type transistor are not circumferentially surrounded by the conductive layer, and wherein one of the first n-type transistor or the second n-type transistor, but not both, is circumferentially surrounded by the conductive layer.

13. A method, comprising:
forming a first gate dielectric layer over a first channel component and forming a second gate dielectric layer over a second channel component, wherein the first gate dielectric layer and the second gate dielectric layer are each undoped;
forming a p-dipole dopant source layer over the second gate dielectric layer;
performing a dipole drive-in process, wherein atoms of the p-dipole dopant source layer are driven into the second gate dielectric layer by the dipole drive-in process, such that the second gate dielectric layer becomes doped;
removing the p-dipole dopant source layer after the dipole drive-in process has been performed; and
depositing an aluminum-free conductive layer over at least one of the first gate dielectric layer or the second gate dielectric layer after the removing of the p-dipole dopant source layer.

14. The method of claim 13, wherein the depositing comprises depositing a first aluminum-free conductive layer that circumferentially wraps around the first gate dielectric layer in a cross-sectional side view and depositing a second aluminum-free conductive layer that circumferentially wraps around the second gate dielectric layer in the cross-sectional side view, and wherein the method further comprises:
forming a gate electrode layer that circumferentially wraps around both the first aluminum-free conductive layer and the second aluminum-free conductive layer in the cross-sectional side view, wherein the gate electrode layer contains an n-type work function metal.

15. The method of claim 13, wherein the depositing comprises depositing the aluminum-free conductive layer that circumferentially wraps around the first gate dielectric layer but not over the second gate dielectric layer in a cross-sectional side view, and wherein the method further comprises:
forming a gate electrode layer that circumferentially wraps around both the aluminum-free conductive layer and the second gate dielectric layer in the cross-sectional side view, wherein the gate electrode layer contains an n-type work function metal.

16. The method of claim 13, wherein the depositing comprises depositing the aluminum-free conductive layer that circumferentially wraps around the second gate dielectric layer but not over the first gate dielectric layer in a cross-sectional side view, and wherein the method further comprises:
forming a gate electrode layer that circumferentially wraps around both the aluminum-free conductive layer and the first gate dielectric layer in the cross-sectional side view, wherein the gate electrode layer contains an n-type work function metal.

17. The method of claim 13, wherein the depositing the aluminum-free conductive layer comprises depositing a titanium nitride layer as the aluminum-free conductive layer.

18. The method of claim 13, wherein:
the first channel component and the first gate dielectric layer are portions of a first n-type transistor;
the second channel component and the second gate dielectric layer are portions of a second n-type transistor; and
the method further comprises:
forming a first p-type transistor over the first n-type transistor and forming a second p-type transistor over the second n-type transistor, including forming a third gate dielectric layer over a third channel component of a first p-type transistor, and forming a fourth gate dielectric layer over a fourth channel component of the second p-type transistor.

19. The method of claim 18, further comprising:
forming an n-type metal gate electrode that circumferentially surrounds the first n-type transistor, the second n-type transistor, the first p-type transistor, and the second p-type transistor in a cross-sectional side view;
removing portions of the n-type metal gate electrode that circumferentially surrounds the first p-type transistor and the second p-type transistor; and
forming a p-type metal gate electrode over a remaining portion of the n-type metal gate electrode, wherein the p-type metal gate electrode circumferentially surrounds both the first p-type transistor and the second p-type transistor in the cross-sectional side view.

20. The method of claim 18, further comprising:
forming an n-type metal gate electrode that circumferentially surrounds both the first n-type transistor and the second n-type transistor, but not the first p-type transistor or the second p-type transistor, in a cross-sectional side view; and
forming a p-type metal gate electrode that circumferentially surrounds both the first p-type transistor and the second p-type transistor in the cross-sectional side view, wherein the p-type metal gate electrode is formed over the n-type metal gate electrode.
